(19) United States
(12) Patent Application Publication
(10) Pub. No.: US 2025/0174482 A1
(43) Pub. Date: May 29, 2025

(54) TRANSFER ROBOT, METHOD OF OPERATING TRANSFER ROBOT, AND SEMICONDUCTOR MANUFACTURING FACILITY

(71) Applicant: SEMES CO., LTD., Cheonan-si (KR)

(72) Inventors: Hee Jae BYUN, Cheonan-si (KR); Kyo Bong KIM, Cheonan-si (KR); Jae Won CHOI, Cheonan-si (KR); Sang Oh KIM, Cheonan-si (KR)

(73) Assignee: SEMES CO., LTD., Cheonan-si (KR)

(21) Appl. No.: 18/957,865

(22) Filed: Nov. 24, 2024

(30) Foreign Application Priority Data
Nov. 24, 2023 (KR) 10-2023-0165839

(51) Int. Cl. H01L 21/68; B65G 47/90; H01L 21/67; H01L 21/687

(52) U.S. Cl. CPC H01L 21/68; B65G 47/905; H01L 21/67196; H01L 21/68707

(57) ABSTRACT

Disclosed is a transfer robot provided in a semiconductor manufacturing facility including a first transfer module and a second transfer module detachably coupled to the first transfer module. The transfer robot transfers a substrate while moving along the first and second transfer modules. The transfer robot includes a moving body moving along first and second tracks respectively mounted to the first and second transfer modules, an encoder module detecting a first scale mounted along the first track and a second scale mounted along the second track to generate a position signal, a controller detecting the position of the transfer robot based on the position signal, and a servo system controlling driving of the moving body in accordance with the detected position. The encoder module includes a first encoder and a second encoder mounted with an interval therebetween along the first track and in the longitudinal direction of the second track.

### CROSS-REFERENCE TO RELATED APPLICATION(S)

This application claims priority under 35 U.S.C. § 119 to Korean Patent Application No. 10-2023-0165839, filed on Nov. 24, 2023 in the Korean Intellectual Property Office, the disclosure of which is incorporated by reference herein in its entirety.

### BACKGROUND OF THE INVENTION

### Field of the Invention

The present invention relates to a transfer robot, a method of operating the transfer robot, and a semiconductor manufacturing facility including the transfer robot.

### Description of the Related Art

A semiconductor (or display) manufacturing process is a process for manufacturing a semiconductor device on a substrate (e.g., wafer), and includes, for example, exposure, deposition, etching, ion implantation, and cleaning. In order to perform each manufacturing process, semiconductor manufacturing facilities, each of which performs a corresponding process, are provided in a clean room of a semiconductor manufacturing plant, and processing is performed on substrates introduced into the semiconductor manufacturing facilities.

In general, a semiconductor manufacturing facility includes a processing module configured to process a substrate and a transfer module configured to transfer a substrate to the processing module and to transfer a completely processed substrate from the processing module. The processing module is provided in plural, and the plurality of processing modules is arranged along the periphery of the transfer module. The processing capacity (processing amount per unit time) of the semiconductor manufacturing facility is determined by the number of processing modules. In order to variably adjust the processing capacity of

a semiconductor manufacturing facility, there has been proposed a platform-type facility allowing some processing modules to be detachably mounted in a semiconductor manufacturing facility. For example, there are a “6+4” type platform facility allowing four processing modules to be additionally mounted in a semiconductor manufacturing facility having six processing modules and a “4+4” type platform facility allowing four processing modules to be additionally mounted in a semiconductor manufacturing facility having four processing modules.

In such a platform-type semiconductor manufacturing facility, a transfer module is also additionally mounted in order to transfer a substrate to the additionally mounted processing modules, and a transfer robot configured to transfer a substrate is moved to the additionally mounted transfer module. When an additional transfer module is mounted, a disconnected section is present on a transfer route, and detection of the position of a transfer robot may be blocked at the disconnected section. Because detection of the position of a transfer robot is necessary to drive the transfer robot, there is a need for a method of detecting the position of the transfer robot at a disconnected section in a platform-type semiconductor manufacturing facility.

### SUMMARY OF THE INVENTION

Therefore, the present invention has been made in view of the above problems, and it is an object of the present invention to provide a transfer robot capable of detecting the position thereof at a disconnected section between transfer modules in a platform-type semiconductor manufacturing facility, a method of operating the transfer robot, and a semiconductor manufacturing facility including the transfer robot.

In accordance with an aspect of the present invention, the above and other objects can be accomplished by the provision of a transfer robot provided in a semiconductor manufacturing facility including a first transfer module and a second transfer module detachably coupled to the first transfer module, the transfer robot being configured to transfer a substrate while moving along the first transfer module and the second transfer module. The transfer robot includes a moving body configured to move along a first track mounted to the first transfer module and a second track mounted to the second transfer module, an encoder module configured to detect a first scale mounted along the first track and a second scale mounted along the second track to generate a position signal, a controller configured to detect the position of the transfer robot based on the position signal, and a servo system configured to control driving of the moving body in accordance with the detected position. The encoder module includes a first encoder and a second encoder mounted with an interval therebetween along the first track and in the longitudinal direction of the second track.

In the embodiment of the present invention, the interval between the first encoder and the second encoder may be greater than an interval between the first scale and the second scale.

In the embodiment of the present invention, the controller may determine the position of the moving body based on a first position signal received from the first encoder and a second position signal received from the second encoder, and the servo system may generate a driving signal in accordance with a difference between the position of the moving body and a target position of the moving body.

In the embodiment of the present invention, the controller may determine the position of the moving body using one of the first position signal and the second position signal.

In the embodiment of the present invention, the controller may detect whether the moving body passes through a section between the first track and the second track, and may switch a position signal for determination of the position of the moving body upon detecting that the moving body passes through the section between the first track and the second track.

In the embodiment of the present invention, the controller may monitor the first position signal and the second position signal, and may determine that the moving body passes through the section between the first track and the second track upon detecting that a discontinuous section occurs in one of the first position signal and the second position signal.

In the embodiment of the present invention, the controller may switch the position signal for determination of the position of the moving body upon detecting that one of the first position signal and the second position signal is restored from the discontinuous section to a continuous section.

In accordance with another aspect of the present invention, there is provided a method of operating the transfer robot described above, the method including determining the position of the moving body based on a position signal received from the encoder module and controlling driving of the moving body in accordance with the position of the moving body. In accordance with a further aspect of the present

invention, there is provided a semiconductor manufacturing facility including a loader module configured to accommodate a cassette configured to receive a substrate, a load lock chamber configured to temporarily store the substrate, a transfer module configured to provide a space to allow a transfer robot transferring the substrate to travel therethrough, and a plurality of processing modules arranged on opposite sides of the transfer module and configured to process the substrate.

The transfer module includes a first transfer module coupled to the load lock chamber and a second transfer module configured to be detachably coupled to the first transfer module.

The first transfer module includes a first track configured to provide a movement path for the transfer robot and a first scale mounted along the first track and including markers arranged for determination of the position of the transfer robot.

The second transfer module includes a second track configured to be connected to the first track and a second scale configured to be connected to the first scale.

The transfer robot includes a moving body configured to move along the first track and the second track, an encoder module configured to detect the first scale mounted along the first track and the second scale mounted along the second track to generate a position signal, a controller configured to detect the position of the transfer robot based on the position signal, and a servo system configured to control driving of the moving body in accordance with the detected position. The encoder module includes a first encoder and a second encoder mounted with an interval therebetween along the first track and in the longitudinal direction of the second track. The interval between the first encoder and the second encoder is greater than an interval between the first scale and the second scale.

### BRIEF DESCRIPTION OF THE DRAWINGS

The above and other objects, features and other advantages of the present invention will be more clearly understood from the following detailed description taken in conjunction with the accompanying drawings, in which:

FIGS. 1 and 2 are views showing the layout of a semiconductor manufacturing facility according to the present invention;

FIGS. 3 and 4 are views for explaining a transfer robot according to the present invention;

FIG. 5 is a block diagram showing the configuration of a driving unit of the transfer robot; and

FIG. 6 is a flowchart showing a method of operating the transfer robot.

### DETAILED DESCRIPTION OF THE INVENTION

Hereinafter, embodiments of the present invention will be described in detail with reference to the accompanying drawings so that those skilled in the art can easily carry out the embodiments. The present invention may, however, be embodied in many different forms, and should not be construed as being limited to the embodiments set forth herein.

Parts irrelevant to description of the present invention will be omitted to clearly describe the present invention, and the same or similar constituent elements will be denoted by the same reference numerals throughout the specification.

In addition, constituent elements having the same configurations in several embodiments will be assigned with the same reference numerals and described only in the representative embodiment, and only constituent elements different from those of the representative embodiment will be described in the other embodiments.

Throughout the specification, when a constituent element is said to be “connected”, “coupled”, or “joined” to another constituent element, the constituent element and the other constituent element may be “directly connected”, “directly coupled”, or “directly joined” to each other, or may be “indirectly connected”, “indirectly coupled”, or “indirectly joined” to each other with one or more intervening elements interposed therebetween. In addition, throughout the specification, when a constituent element is referred to as “comprising”, “including”, or “having” another constituent element, the constituent element should not be understood as excluding other elements, so long as there is no special conflicting description, and the constituent element may include at least one other element.

Unless otherwise defined, all terms used herein, which include technical or scientific terms, have the same meanings as those generally appreciated by those skilled in the art. The terms, such as ones defined in common dictionaries, should be interpreted as having the same meanings as terms in the context of pertinent technology, and should not be interpreted as having ideal or excessively formal meanings unless clearly defined in the specification.

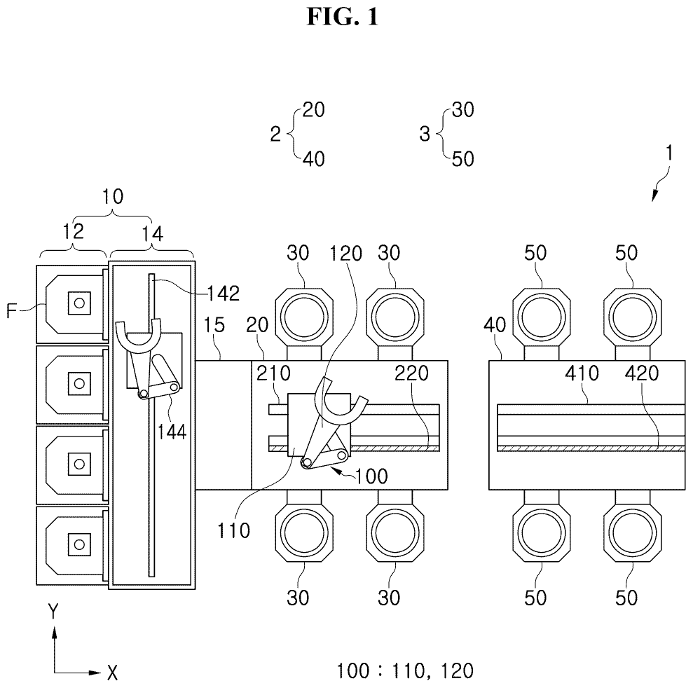

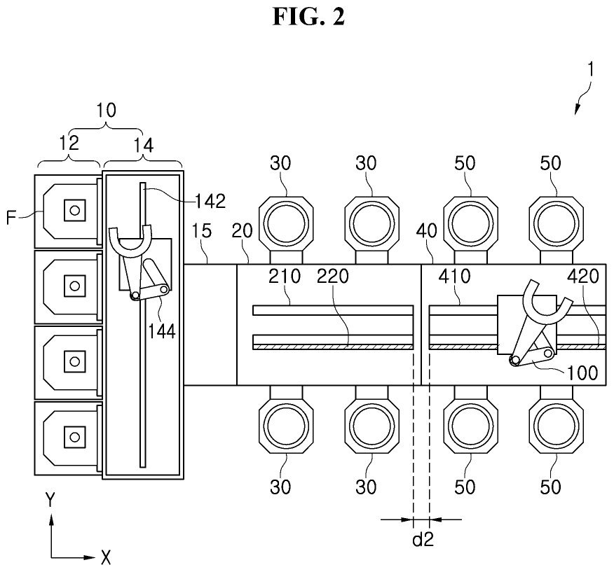

FIGS. 1 and 2 are views showing the layout of a semiconductor manufacturing facility 1 according to the present invention. FIG. 1 shows the semiconductor manufacturing facility 1 in a state in which a second transfer module 40 and a second processing module 50 are separated therefrom, and FIG. 2 shows the semiconductor manufacturing facility 1 in a state in which the second transfer module 40 and the second processing module 50 are coupled thereto. The semiconductor manufacturing facility 1 to which the present invention is applicable is an apparatus configured to perform semiconductor processing processes, such as etching, cleaning, coating, development, and deposition. The present invention is not limited to an apparatus configured to perform a specific process, and may be applied to any type of facility.

The semiconductor manufacturing facility 1 according to the present invention includes a loader module 10 configured to unload or load a substrate from or into a cassette F, a load lock chamber 15 configured to temporarily store the substrate, a transfer module 2 configured to provide a space in which a transfer robot 100 travels to transfer the substrate, and a plurality of processing modules 3 arranged on opposite sides of the transfer module 2 and configured to process the substrate. The transfer module 2 includes a first transfer module 20 coupled adjacent to the loader module 10 and a second transfer module 40 detachably coupled to the first transfer module 20. The processing modules 3 include first processing modules 30 coupled to opposite sides of the first transfer module 20 and second processing modules 50 coupled to opposite sides of the second transfer module 40.

The first transfer module 20 includes a first track 210 configured to provide a movement path for the transfer robot 100 and a first scale 220 mounted along the first track 210 and including markers 220M arranged for determination of the position of the transfer robot 100. The second transfer module 40 includes a second track 410 configured to be coupled to the first track 210 with an interval d2 therebetween and a second scale 420 configured to be coupled to the first scale 220 with the interval d2 therebetween.

The loader module 10 includes a load port 12 on which a cassette F configured to receive a substrate is seated and an index unit 14 configured to unload a substrate from the cassette F seated on the load port 12 or to load a completely processed substrate into the cassette F. The load port 12 may be provided in plural, and the plurality of load ports 12 may be disposed in a predetermined direction (e.g., Y-axis direction) on an outer side of the semiconductor manufacturing facility 1. After the cassette F transferred by an overhead hoist transport (OHT) is seated on each of the load ports 12, a door of the cassette F may be opened. The index unit 14 may be disposed adjacent to the load ports 12. The index unit 14 may include an index guide member 142 disposed in the arrangement direction (Y-axis direction) of the load ports 12 and an index robot 144 configured to move along the index guide member 142 to transfer a substrate. The index robot 144 may receive a substrate from the cassette F and then may transfer the received substrate to the load lock chamber 15 so that the substrate is temporarily stored in the load lock chamber 15, or may receive a substrate temporarily stored in the load lock chamber 15 and then may transfer the received substrate to the interior of the cassette F.

The first transfer module 20 may receive a substrate from the load lock chamber 15 and then may transfer the received substrate to the first processing module 30, or may transfer a substrate completely processed in the first processing module 30 to the load lock chamber 15. The first transfer module 20 includes a housing including an inner space defined therein, a first track 210 provided on a bottom surface of the housing, and a first scale 220 mounted along the first track 210. A door through which a substrate is transferred to the first processing module 30 may be provided on a sidewall of the first transfer module 20. The first track 210 is disposed in the arrangement direction (X-axis direction) of the first processing modules 30 on an inner bottom surface of the first transfer module 20. The transfer robot 100 may transfer a substrate to the first processing module 30 while moving along the first track 210. A structure for coupling to the second transfer module 40 may be provided on a wall of the first transfer module 20 opposite the load lock chamber 15 (wall of an end portion of the first transfer module 20 in the X-axis direction). An opening and a shielding mechanism configured to selectively open the opening may be located at the wall of the first transfer module 20 opposite the load lock chamber 15 (wall of an end portion of the first transfer module 20 in the X-axis direction).

The first processing module 30 is an apparatus configured to process a substrate, and may include one or more processing chambers. The first processing module 30 may be provided in plural, and the plurality of first processing modules 30 may be disposed in a predetermined direction (e.g., X-axis direction) on opposite sides of the first transfer module 20. The first processing modules 30 may perform the same process or may perform different processes. For example, some of the first processing modules 30 may perform an etching process on the substrate, and the remaining ones of the first processing modules 30 may perform a cleaning process on the substrate having undergone the etching process.

As an expandable module capable of being selectively separated from or mounted to the platform-type semiconductor manufacturing facility 1, the second transfer module 40 and the second processing module 50 may be included in the semiconductor manufacturing facility 1. The second transfer module 40 may be coupled to the first transfer module 20 in an extended form. Optionally, the second transfer module 40 may be separated from the first transfer module 20.

The second transfer module 40 may have the same structure as the first transfer module 20. The second transfer module 40 includes a housing including an inner space defined therein, a second track 410 provided on a bottom surface of the housing, and a second scale 420 mounted along the second track 410. A door through which a substrate is transferred to the second processing module 50 may be provided on a sidewall of the second transfer module 40. The second track 410 is disposed in the arrangement direction (X-axis direction) of the second processing modules 50 on an inner bottom surface of the second transfer module 40. The transfer robot 100 may transfer a substrate to the second processing module 50 while moving along the second track 410 via the first track 210. A structure for coupling to the first transfer module 20 may be provided on a wall of the second transfer module 40 facing the first transfer module 20 (wall of an end portion of the second transfer module 40 in the −X-axis direction). An opening and a shielding mechanism configured to selectively open the opening may be located at the wall of the second transfer module 40 facing the first transfer module 20 (wall of an end portion of the second transfer module 40 in the −X-axis direction). A wall of the second transfer module 40 opposite the first transfer module 20 (wall of an end portion of the second transfer module 40 in the +X-axis direction) may be closed or may be configured to allow an additional transfer module to be coupled thereto.

The second processing module 50 is an apparatus configured to process a substrate, and may include one or more processing chambers. The second processing module 50 may be provided in plural, and the plurality of second processing modules 50 may be disposed in a predetermined direction (e.g., X-axis direction) on opposite sides of the second transfer module 40. The second processing modules 50 may perform the same process or may perform different processes. For example, some of the second processing modules 50 may perform an etching process on the substrate, and the remaining ones of the second processing modules 50 may perform a cleaning process on the substrate having undergone the etching process.

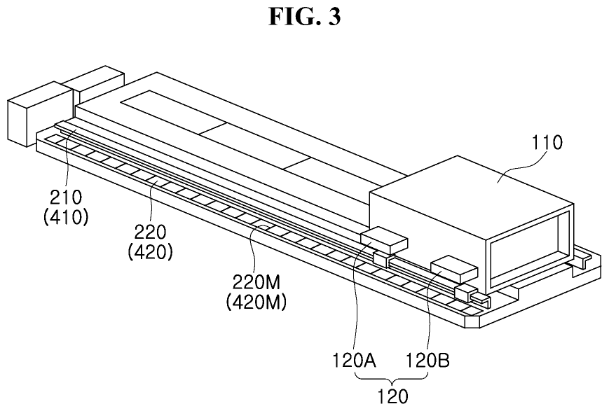

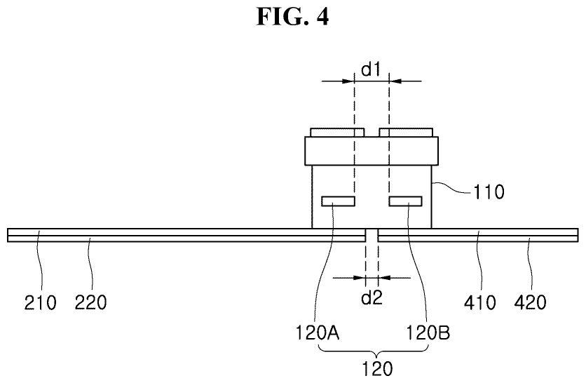

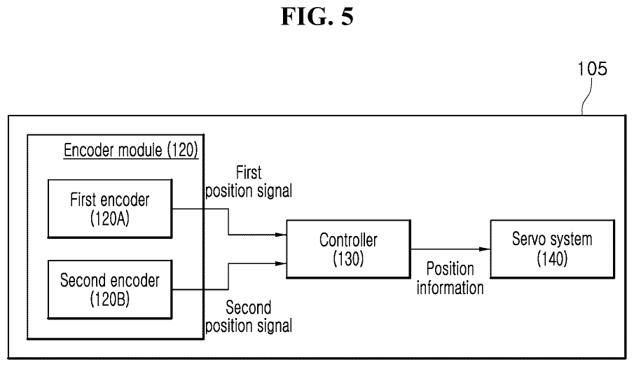

FIGS. 3 and 4 are views for explaining the transfer robot 100 according to the present invention. FIG. 5 is a block diagram showing the configuration of a driving unit 105 of the transfer robot 100.

The transfer robot 100 transfers a substrate stored in the load lock chamber 15 to the first processing module 30 or the second processing module 50. Additionally, the transfer robot 100 transfers a substrate completely processed in the first processing module 30 or the second processing module 50 to the load lock chamber 15. The transfer robot 100 broadly includes a moving body 110 configured to move along the first track 210 and the second track 410 and a driving unit 105 configured to generate power for movement of the moving body 110. The driving unit 105 includes various driving devices mounted inside or outside the moving body 110.

The transfer robot 100 includes a moving body 110 configured to move along the first track 210 mounted to the first transfer module 20 and the second track 410 mounted to the second transfer module 40, an encoder module 120 configured to detect the first scale 220 mounted along the first track 210 and the second scale 420 mounted along the second track 410 to generate a position signal, a controller 130 configured to detect the position of the transfer robot 100 based on the position signal, and a servo system 140 configured to control driving of the moving body 110 in accordance with the detected position. The encoder module 120 includes a first encoder 120A and a second encoder 120B mounted with an interval d1 therebetween along the first track 210 and in the longitudinal direction X of the second track 410.

The moving body 110 is a structure configured to be moved along the first track 210 and the second track 410 by the driving unit (e.g., linear motor) of the servo system 140. A robot arm and a robot hand 120 are mounted on the moving body 110 in order to handle a substrate. As shown in FIG. 3, the encoder module 120 may be mounted on one side of the moving body 110. The encoder module 120 detects markers 220M or 420M engraved on the first scale 220 or the second scale 420, and generates a position signal for position determination. Referring to FIG. 5, a first position signal generated by the first encoder 120A and a second position signal generated by the second encoder 120B may be provided to the controller 130.

The controller 130 is a circuit configured to control overall operation of the transfer robot 100. The controller 130 determines the current position of the transfer robot 100 based on a position signal provided from a sensor or the encoder module 120 mounted to the transfer robot 100, and provides position information to the servo system 140. The servo system 140 may generate a driving signal using the position information, and may transmit the driving signal to a driving device (e.g., linear motor). The servo system 140 performs operation for moving the transfer robot 100 to a target position provided from a processor (not shown) configured to control operation of the semiconductor manufacturing facility 1. The servo system 140 may include a driving controller configured to generate a driving signal and a driving device (e.g., linear motor) configured to operate in response to the driving signal. For example, the servo system 140 may generate a driving signal (e.g., acceleration or deceleration) in accordance with a difference between a target position provided from an upper-level control system and position information (current position) provided from the controller 130. The motor controlled by the servo system 140 is configured to be driven in response to a driving signal, and generates power to allow the moving body 110 to move along the first track 210 or the second track 410.

Referring to FIG. 3, the first track 210 is mounted in the horizontal direction (X-axis direction) on the bottom surface of the first transfer module 20, and the first scale 220 is mounted along the first track 210. The first scale 220 is a structure engraved with markers 220M for determination of the position of the transfer robot 100. In the first scale 220, the markers 220M for position determination may be optical markers or may be magnets arranged so as to induce an electromagnetic signal of a specific pattern. Similarly, the second track 410 is mounted in the horizontal direction (X-axis direction) on the bottom surface of the second transfer module 40, and the second scale 420 is mounted along the second track 410. The second track 410 and the second scale 420 may be configured identically to the first track 210 and the first scale 220, respectively.

As shown in FIG. 2, when the second transfer module 40 is coupled to the first transfer module 20, an interval d2 may be formed between the first track 210 and the second track 410, and detection of the position of the transfer robot 100 may be interrupted at a section in which the interval d2 is formed. The transfer robot 100 according to the present invention includes the first encoder 120A and the second encoder 120B disposed so as to be spaced apart from each other in the longitudinal direction of the first track 210 and the second track 410, and combines a first position signal from the first encoder 120A and a second position signal from the second encoder 120B with each other or selectively uses one of the first and second position signals, thereby enabling continuous detection of the position of the transfer robot 100.

According to the embodiment of the present invention, the interval d1 between the first encoder 120A and the second encoder 120B may be formed to be greater than the interval d2 between the first scale 220 and the second scale 420. As shown in FIG. 4, the interval d2 is formed between the first scale 220 and the second scale 420, and the interval d1 between the first encoder 120A and the second encoder 120B mounted to the transfer robot 100 is greater than the interval d2.

According to the embodiment of the present invention, the controller 130 determines the position of the moving body 110 based on the first position signal received from the first encoder 120A and the second position signal received from the second encoder 120B. The servo system 140 generates a driving signal in accordance with a difference between the position of the moving body 110 and the target position of the moving body 110.

The controller 130 determines the position of the moving body 110 using one of the first position signal and the second position signal. For example, when the moving body 110 is located at the first transfer module 20, the controller 130 determines the position of the moving body 110 using the first position signal. When the moving body 110 is located at the second transfer module 40, the controller 130 determines the position of the moving body 110 using the second position signal.

The controller 130 switches the position signal for position determination upon detecting that the moving body 110 passes through the section between the first track 210 and the second track 410. Upon detecting that the moving body 110 reaches the second track 410 of the second transfer module 40 from the first track 210 of the first transfer module 20, the controller 130 may determine the position of the moving body 110 using the second position signal provided from the second encoder 120B. Conversely, upon detecting that the moving body 110 reaches the first track 210 of the first transfer module 20 from the second track 410 of the second transfer module 40, the controller 130 may determine the position of the moving body 110 using the first position signal provided from the first encoder 120A.

The controller 130 may monitor the first position signal and the second position signal. Upon detecting that a discontinuous section occurs in one of the first position signal and the second position signal, the controller 130 may determine that the moving body 110 passes through the section between the first track and the second track. The controller 130 monitors the first position signal and the second position signal input through two ports. The first position signal and the second position signal are signals (constant analog signals) corresponding to continuous sections in a state in which the first encoder 120A and the second encoder 120B detect the first scale 220 or the second scale 420. When the moving body 110 passes through the disconnected section between the first track 210 and the second track 410, a discontinuous section occurs in the first position signal or the second position signal. The discontinuous section is a signal section in which the signal is cut off or signal distortion of a predetermined level or more occurs. When the moving body 110 moves from the first transfer module 20 to the second transfer module 40, a discontinuous section occurs in the second position signal generated by the second encoder 120B. In this case, the controller 130 may determine that the moving body 110 has entered the disconnected section between the first transfer module 20 and the second transfer module 40 from the first transfer module 20. When the moving body 110 moves from the second transfer module 40 to the first transfer module 20, a discontinuous section occurs in the first position signal generated by the first encoder 120A. In this case, the controller 130 may determine that the moving body 110 has entered the disconnected section between the first transfer module 20 and the second transfer module 40 from the second transfer module 40.

Upon detecting that one of the first position signal and the second position signal is restored from the discontinuous section to a continuous section, the controller 130 may switch the position signal for determination of the position of the moving body 110. For example, when a discontinuous section is detected in the second position signal and then a continuous section is detected in the second position signal, the controller 130 may switch the position signal for determination of the position of the moving body 110 from the first position signal to the second position signal. Conversely, when a discontinuous section is detected in the first position signal and then a continuous section is detected in the first position signal, the controller 130 may switch the position signal for determination of the position of the moving body 110 from the second position signal to the first position signal.

According to the present invention, the transfer robot 100 includes the first encoder 120A and the second encoder 120B mounted thereto with the interval d1 therebetween, and selectively uses the position signals provided from the first encoder 120A and the second encoder 120B, thereby determining the position of the moving body 110. Thus, even when a disconnected section is present between the first track 210 and the second track 410, the position of the moving body 110 may be continuously detected. Accordingly, in the expandable semiconductor manufacturing facility 1 in which the second transfer module 40 is capable of being detachably coupled to the first transfer module 20, it may be possible to reduce inconvenience of having to reset the transfer robot 100 with respect to the second scale 420 whenever coupling the second transfer module 40 to the first transfer module 20 and to rapidly drive the semiconductor manufacturing facility 1.

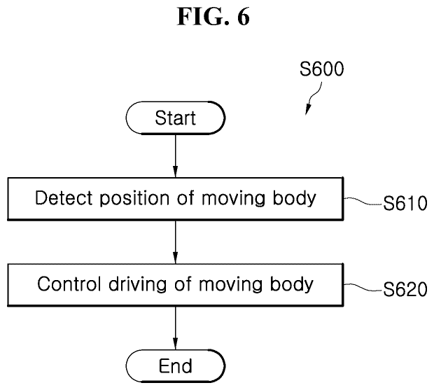

The present invention may provide a method of operating the transfer robot 100 described above with reference to FIGS. 1 to 5. FIG. 6 is a flowchart showing a method S600 of operating the transfer robot 100. The method S600 of operating the transfer robot 100 according to the present invention includes a step S610 of determining the position of the moving body 110 based on a position signal received from the encoder module 120 and a step S620 of controlling driving of the moving body 110 in accordance with the position of the moving body 110.

In step S610, the encoder module 120 transmits a position signal for determination of the position of the moving body 110 to the controller 130 using the first scale 220 or the second scale 420, and the controller 130 determines the position of the moving body 110 based on the position signal. In step S620, the controller 130 provides position information to the servo system 140, and the servo system 140 controls driving of the moving body 110 in accordance with the position information. For example, the servo system 140 may control acceleration or deceleration in accordance with the position of the moving body 110.

Step S610 of determining the position of the moving body 110 includes a step of determining the position of the moving body 110 based on a first position signal received from the first encoder 120A and a second position signal received from the second encoder 120B. Step S620 of controlling driving of the moving body 110 includes a step of generating a driving signal in accordance with a difference between the position of the moving body 110 and the target position of the moving body 110.

Step S610 of determining the position of the moving body 110 includes a step of determining the position of the moving body 110 using one of the first position signal and the second position signal. Step S610 of determining the position of the moving body 110 includes a step of detecting whether the moving body 110 passes through the section between the first track 210 and the second track 410 and a step of switching the position signal for determination of the position of the moving body 110 upon detecting that the moving body 110 passes through the section between the first track 210 and the second track 410. The step of detecting whether the moving body 110 passes through the section between the first track 210 and the second track 410 includes a step of monitoring the first position signal and the second position signal and a step of determining that the moving body 110 passes through the section between the first track 210 and the second track 410 upon detecting that a discontinuous section occurs in one of the first position signal and the second position signal. The step of switching the position signal includes a step of switching the position signal for determination of the position of the moving body 110 upon detecting that one of the first position signal and the second position signal is restored from the discontinuous section to a continuous section.

As is apparent from the above description, according to the present invention, since a first encoder and a second encoder are disposed in the longitudinal direction of a track, it may be possible to detect the position of a transfer robot even at a disconnected section between transfer modules.

Although the preferred embodiments of the present invention have been disclosed for illustrative purposes, those skilled in the art will appreciate that various modifications, additions and substitutions are possible, without departing from the scope and spirit of the invention.

The scope of the present invention should be defined only by the accompanying claims, and all technical ideas within the scope of equivalents to the claims should be construed as falling within the scope of the invention.

What is claimed is:

1. A transfer robot provided in a semiconductor manufacturing facility comprising a first transfer module and a second transfer module detachably coupled to the first transfer module, the transfer robot being configured to transfer a substrate while moving along the first transfer module and the second transfer module, the transfer robot comprising:
a moving body configured to move along a first track mounted on the first transfer module and a second track mounted on the second transfer module;
an encoder module configured to detect a first scale mounted along the first track and a second scale mounted along the second track to generate a position signal representing a position of the moving body;
a controller configured to detect the position of the moving body based on the position signal; and
a servo system configured to control driving of the moving body in accordance with the detected position of the moving body,
wherein the encoder module comprises a first encoder and a second encoder mounted with an interval therebetween along the first track and in a longitudinal direction of the second track.

2. The transfer robot according to claim 1, wherein the interval between the first encoder and the second encoder is greater than an interval between the first scale and the second scale.

3. The transfer robot according to claim 1, wherein the controller determines the position of the moving body based on a first position signal received from the first encoder and a second position signal received from the second encoder, and
wherein the servo system generates a driving signal in accordance with a difference between the position of the moving body and a target position of the moving body.

4. The transfer robot according to claim 3, wherein the controller determines the position of the moving body using one of the first position signal and the second position signal.

5. The transfer robot according to claim 3, wherein the controller detects whether the moving body passes through a section between the first track and the second track, and switches a position signal for determination of the position of the moving body from the first position signal to the second signal or from the second position signal to the first signal upon detecting that the moving body passes through the section between the first track and the second track.

6. The transfer robot according to claim 5, wherein the controller monitors the first position signal and the second position signal, and determines that the moving body passes through the section between the first track and the second track upon detecting that a discontinuous section occurs in one of the first position signal and the second position signal.

7. The transfer robot according to claim 6, wherein the controller switches the position signal for determination of the position of the moving body upon detecting that one of the first position signal and the second position signal is restored from the discontinuous section to a continuous section.

8. A method of operating the transfer robot according to claim 1, the method comprising:
determining a position of the moving body based on a position signal received from the encoder module; and
controlling driving of the moving body in accordance with the position of the moving body.

9. The method according to claim 8, wherein the interval between the first encoder and the second encoder is greater than an interval between the first scale and the second scale.

10. The method according to claim 8, wherein the determining a position of the moving body comprises determining the position of the moving body based on a first position signal received from the first encoder and a second position signal received from the second encoder, and
wherein the controlling driving of the moving body comprises generating a driving signal in accordance with a difference between the position of the moving body and a target position of the moving body.

11. The method according to claim 10, wherein the determining the position of the moving body comprises determining the position of the moving body using one of the first position signal and the second position signal.

12. The method according to claim 11, wherein the determining the position of the moving body further comprises:
detecting whether the moving body passes through a section between the first track and the second track; and
switching a position signal for determination of the position of the moving body from the first position signal to the second signal or from the second position signal to the first signal upon detecting that the moving body passes through the section between the first track and the second track.

13. The method according to claim 12, wherein the detecting whether the moving body passes through a section between the first track and the second track comprises:
monitoring the first position signal and the second position signal; and
determining that the moving body passes through a disconnected section between the first track and the second track upon detecting that a discontinuous section occurs in one of the first position signal and the second position signal.

14. The method according to claim 13, wherein the switching a position signal comprises switching the position signal for determination of the position of the moving body upon detecting that one of the first position signal and the second position signal is restored from the discontinuous section to a continuous section.

15. A semiconductor manufacturing facility comprising:
a loader module configured to accommodate a cassette configured to receive a substrate;
a load lock chamber configured to temporarily store the substrate;
a transfer module configured to provide a space to allow a transfer robot transferring the substrate to travel therethrough; and
a plurality of processing modules arranged on opposite sides of the transfer module, the plurality of processing modules being configured to process the substrate,
wherein the transfer module comprises a first transfer module coupled to the load lock chamber and a second transfer module configured to be detachably coupled to the first transfer module,
wherein the first transfer module comprises:
a first track configured to provide a movement path for the transfer robot; and
a first scale mounted along the first track, the first scale comprising markers arranged for determination of a position of the transfer robot,
wherein the second transfer module comprises:
a second track configured to be connected to the first track; and
a second scale configured to be connected to the first scale,
wherein the transfer robot comprises:
a moving body configured to move along the first track and the second track;
an encoder module configured to detect the first scale mounted along the first track and the second scale mounted along the second track to generate a position signal;
a controller configured to detect a position of the transfer robot based on the position signal; and
a servo system configured to control driving of the moving body in accordance with the detected position,
wherein the encoder module comprises a first encoder and a second encoder mounted with an interval therebetween along the first track and in a longitudinal direction of the second track, and
wherein the interval between the first encoder and the second encoder is greater than an interval between the first scale and the second scale.

16. The semiconductor manufacturing facility according to claim 15, wherein the controller determines a position of the moving body based on a first position signal received from the first encoder and a second position signal received from the second encoder, and
wherein the servo system generates a driving signal in accordance with a difference between the position of the moving body and a target position of the moving body.

17. The semiconductor manufacturing facility according to claim 16, wherein the controller determines the position of the moving body using one of the first position signal and the second position signal.

18. The semiconductor manufacturing facility according to claim 17, wherein the controller detects whether the moving body passes through a section between the first track and the second track, and switches a position signal for determination of the position of the moving body from the first position signal to the second signal or from the second position signal to the first signal upon detecting that the moving body passes through the section between the first track and the second track.

19. The semiconductor manufacturing facility according to claim 18, wherein the controller monitors the first position signal and the second position signal, and determines that the moving body passes through the section between the first track and the second track upon detecting that a discontinuous section occurs in one of the first position signal and the second position signal.

20. The semiconductor manufacturing facility according to claim 19, wherein the controller switches the position signal for determination of the position of the moving body upon detecting that one of the first position signal and the second position signal is restored from the discontinuous section to a continuous section.
